(19) United States
(12) Patent Application Publication
(10) Pub. No.: US 2015/0340382 A1
(43) Pub. Date: Nov. 26, 2015

(54) DISPLAY SUBSTRATE AND MANUFACTURING METHOD THEREOF, DISPLAY DEVICE

(71) Applicants: BOE TECHNOLOGY GROUP CO., LTD., Beijing (CN); BEIJING BOE DISPLAY TECHNOLOGY CO., LTD., Beijing (CN)

(72) Inventors: MENGJIE WANG, BEIJING (CN); YUFAN DU, BEIJING (CN); YUQIONG CHEN, BEIJING (CN)

(21) Appl. No.: 14/376,455

(22) PCT Filed: Nov. 29, 2013
(86) PCT No.: PCT/CN2013/088136

§ 371 Date: Aug. 4, 2014

(30) Foreign Application Priority Data
May 28, 2013 (CN) 201310202912.2

(51) Int. Cl. H01L 27/12; C03B 32/02; C30B 1/02; C30B 29/16; G02F 1/1335; G02F 1/1368

(52) U.S. Cl. CPC H01L 27/1218; G02F 1/133514; G02F 1/1368; C30B 1/023; C30B 29/16; C03B 32/02

(57) ABSTRACT

A display substrate (10) and manufacturing method thereof, and a display device are provided. The display substrate (10) includes: a base substrate (100) and a display element structure (200) located on the base substrate (100), wherein, the base substrate (100) has a crystal layer (100a) in which crystal grains are arranged in a predetermined direction.

### TECHNICAL FIELD

Embodiments of the present invention relate to a display substrate and manufacturing method thereof, a display device.

### BACKGROUND

As illustrated in FIG. 1, a TFT-LCD (Thin Film Transistor-Liquid Crystal Display) mainly includes an array substrate 20, a color filter substrate 30 and a liquid crystal layer 40 located between the two substrates. Besides, it further includes a first polarizer 50 located on a side of the array substrate opposite to the liquid crystal layer, and a second polarizer 60 located on a side of the color filter substrate opposite to the liquid crystal layer. The array substrate 20 includes a first glass substrate 20a, and the color filter substrate includes a second glass substrate 30a.

However, in view of a thinning demand on a display zone, both the first glass substrate 20a and the second glass substrate 30a may be made to be relatively thin, and this will cause the first glass substrate 20a and the second glass substrate 30a to become relatively fragile.

In addition, as regards a polarizer, polarization property of iodine molecules is vulnerable under high temperature and high humidity during its manufacture, easily leading to the occurrence of various mura (poor quality of pictures) phenomena; it may also suffer from wear-and-tear during its use, and during the attachment, foam or other undesirable thing is liable to appear, and such a problem that the accuracy of attachment is low or the like occurs.

### SUMMARY

According to an embodiment of the invention, there is provided a display substrate, comprising a base substrate and a display element structure located on the base substrate, wherein, the base substrate has a crystal layer in which crystal grains are arranged in a predetermined direction.

In an example, the crystal layer lies in one surface layer of the base substrate.

In an example, a thickness of the crystal layer is equal to a total thickness of the base substrate.

In an example, the crystal layer is a strontium barium niobate crystal layer.

In an example, the base substrate is a microcrystalline glass substrate.

In an example, the display substrate is an array substrate, and the display element structure on the base substrate includes a thin film transistor and a pixel electrode.

In an example, the display panel is a color filter substrate, and the display element structure on the base substrate includes a black matrix and a color filter.

In an example, the crystal layer lies in a surface layer of the base substrate at a side opposite to that for forming the display element structure.

According to another embodiment of the invention, there is provided a manufacturing method of a display substrate, comprising the following steps:

preparing a base substrate, wherein, the base substrate has a crystal layer in which crystal grains are arranged in a predetermined direction;

forming a display element structure on the base substrate.

In an example, the crystal layer is formed at one surface of the base substrate.

In an example, a thickness of the crystal layer is equal to a total thickness of the base substrate.

In an example, the preparing of the base substrate includes:

heating an original glass, so that crystal nuclei are formed in the original glass;

heating the original glass with the formed crystal nuclei, so that crystal grains grow;

conducting a grain-oriented microcrystallization treatment when it reaches a temperature range of crystal precipitation, so as to form a crystal layer with crystal grains arranged in the predetermined direction in the base substrate.

In an example, in the grain-oriented microcrystallization treatment, a gradient temperature field is applied to the glass, so that crystal grains are guided to grow according to the predetermined direction.

According to still another embodiment of the invention, there is provided a display device, comprising the display substrate according to embodiments of the invention.

In an example, the display device includes two of the stated display substrates that are disposed opposite to each other, one of the display substrates is an array substrate, and the other one is a color filter substrate;

the display device further includes a liquid crystal layer disposed between the array substrate and the color filter substrate.

In an example, the crystal layer of the base substrate located in the array substrate and the crystal layer of the base substrate located in the color filter substrate have a polarizing function, and polarizing directions of the crystal layers of the base substrate located in the array substrate and the base substrate located in the color filter substrate are perpendicular to each other.

In an example, the crystal layer in the base substrate in the array substrate is located on a side of the array substrate facing away from the liquid crystal layer; and the crystal layer in the base substrate in the color filter substrate is located on a side of the color filter substrate facing away from the liquid crystal layer.

Regarding a display substrate and manufacturing method and a display device provided by embodiments of the invention, the display substrate includes a base substrate and a display element structure located on the base substrate, wherein, the base substrate has a crystal layer in which crystal grains are arranged along a preset direction. As such, on one hand, the base substrate has a higher mechanical strength than common glass owing to the fact that it has a crystal layer in which crystal grains are arranged orderly, and thus, as compared to a common glass substrate in prior art, the base substrate in the display substrate provided by the invention can avoid from a fragile phenomenon. On the other hand, when the display substrate is applied to a display device, it is applicable to a display equipment that requires an incident light to be polarized light owing to the fact that the base substrate has a crystal layer with orderly arranged crystal grains that allows an incident light to turn into a polarized light, and thus, as compared to the case in prior art that a polarizer needs to be provided additionally, according to the invention, thickness of the display device can be reduced, and problems caused by the easy wear of a polarizer and poor attachment and the occurrence of mura phenomena can be avoided.

### BRIEF DESCRIPTION OF THE DRAWINGS

In order to illustrate the technical solution of the embodiments of the invention more clearly, the drawings of the embodiments will be briefly described below; it is obvious that the drawings as described below are only related to some embodiments of the invention, but are not limitative of the invention.

FIG. 1 is a structurally schematic view illustrating a liquid crystal display device provided by prior art;

FIG. 2 is a first structurally schematic view illustrating a display substrate provided by an embodiment of the invention;

FIG. 3 is a second structurally schematic view illustrating a display substrate provided by an embodiment of the invention;

FIG. 4 is a structurally schematic view illustrating an array substrate provided by an embodiment of the invention;

FIG. 5 is a structurally schematic view illustrating a color filter substrate provided by an embodiment of the invention;

FIG. 6 is a schematic view illustrating a flow chart for manufacturing a display substrate provided by an embodiment of the invention;

FIG. 7 is a first structurally schematic view illustrating a display device provided by an embodiment of the invention;

FIG. 8 is a second structurally schematic view illustrating a display device provided by an embodiment of the invention.

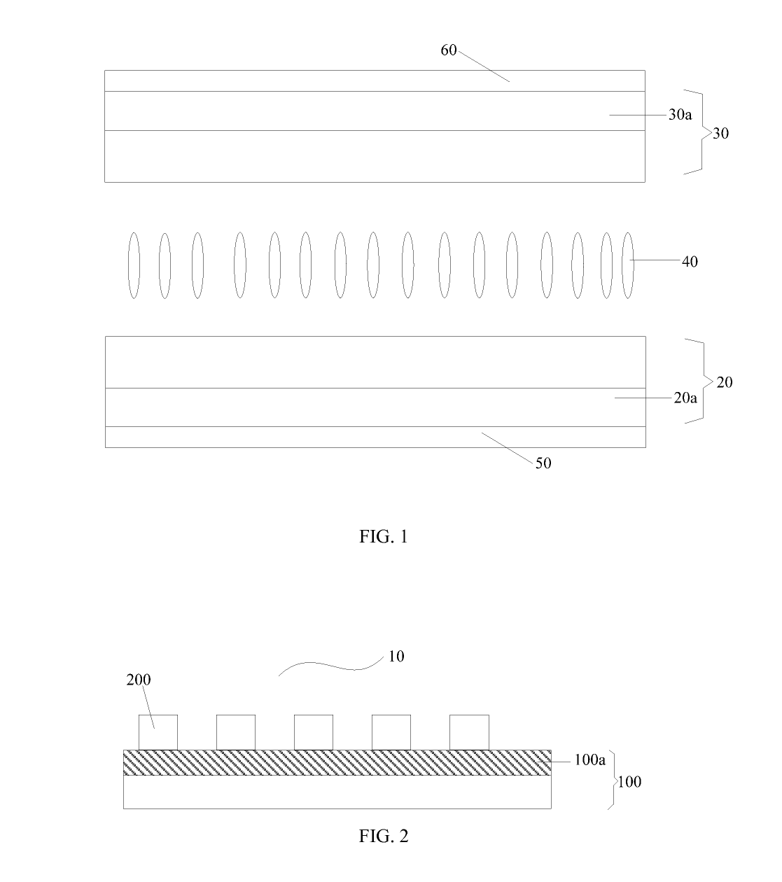

### DETAILED DESCRIPTION

In order to make objects, technical details and advantages of the embodiments of the invention apparent, hereinafter, the technical solutions of the embodiments of the invention will be described in a clearly and fully understandable way in connection with the drawings related to the embodiments of the invention. It is obvious that the described embodiments are just a part but not all of the embodiments of the invention. Based on the described embodiments of the invention, those ordinarily skilled in the art can obtain other embodiment(s), without any inventive work, which come(s) into the scope sought for protection by the invention.

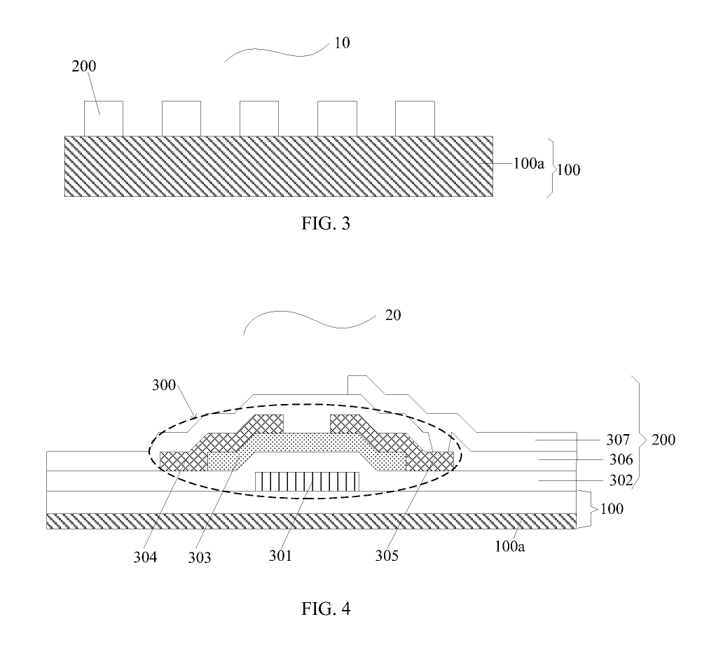

According to an embodiment of the invention, there is provided a display substrate 10. As illustrated in FIG. 2 and FIG. 3, the display substrate includes: a base substrate 100 and a display element structure 200 located on the base substrate. The base substrate 100 has a crystal layer 100a in which crystal grains are arranged along a predetermined direction. The crystal grains being arranged along a predetermined direction here means that directions of crystalline optical axes of crystal grains are arranged along a predetermined direction.

In an example, the crystalline structure may be a tetragonal structure, and meanwhile, they are uniaxial crystals; in this case, direction of a crystalline optical axis coincides with the length direction of a crystal grain. However, embodiments of the invention are not limited to this.

The base substrate here is just a microcrystalline glass substrate, where, microcrystalline glass is a special composite material, which is a polycrystalline solid material in which a crystal phase and a glass phase coexist and obtained by reheating an original glass subjected to high-temperature melting and annealing treatment and controlling the crystal precipitation.

It is to be noted that, firstly, the display element structure 200 refers to such a structure that is essential for implementing display and is composed of patterns of individual layers. For example, as for one smallest display unit of a liquid crystal display device, on an array substrate, the display element structure includes a thin film transistor, a pixel electrode and so on; on a color filter substrate, the display element structure includes a red or green or blue color filter, a black matrix and so on; and certainly, it further includes some necessary pattern layers such as a protective layer, etc., or some pattern layers that are added to improve the display effect or suppress some defects. Thus, in embodiments of the invention, the display element may be understood as patterns disposed on individual layers of a base substrate with respect to one smallest display unit of a display device, and the display substrate 10 includes a number of display element structures 200.

Secondly, thickness of the crystal layer 100a may be set according to an actual manufacturing process, and no limit will be set on it here.

Thirdly, in embodiments of the invention, the crystal layer 100a with crystal grains arranged along a predetermined direction allows an incident, natural light to turn into a polarized light after it passes through the crystal layer 100a, and therefore, the predetermined direction needs to be determined according to a required direction of the polarized light and material of the crystal layer 100a. No limit will be set on it here.

For example, the stated crystal layer is a structure in which crystal grains formed by crystallization and a glass phase coexist.

Regarding a display substrate 10 provided by an embodiment of the invention, the display substrate 10 includes a base substrate 100 and a display element structure 200 located on the base substrate, wherein, the base substrate 100 has a crystal layer 100a in which crystal grains are arranged along a predetermined direction. As such, on one hand, the base substrate 100 has a higher mechanical strength than common glass owing to the fact that it has a crystal layer 100a in which crystal grains are arranged orderly, and thus, as compared to a common glass substrate in prior art, the base substrate 100 in the display substrate provided by the invention can avoid from a fragile phenomenon. On the other hand, when the display substrate 10 is applied to a display device, it is applicable to a display equipment that requires an incident light to be a polarized light owing to the fact that the base substrate 100 has a crystal layer 100a with orderly arranged crystal grains that allows an incident light to turn into a polarized light (namely, which has a polarizing function), and thus, as compared to the case in prior art that a polarizer needs to be provided additionally, according to the invention, thickness of the display device can be reduced, and problems caused by the easy wear of a polarizer and poor attachment, and the occurrence of mura phenomena can be avoided.

In an example, as illustrated in FIG. 2, the crystal layer 100a lies in one surface layer of the base substrate 100.

In general, at the preliminary stage of heat treatment, a crystal layer 100a with crystal grains arranged along a certain direction will be grown on each of two surfaces of a substrate at the same time. However, on condition that crystal precipitation is insufficient, bubbles that are squeezed out by crystal precipitation, unidirectional precipitation matters or the like may be present in the middle part of the substrate. Thus, herein, it is possible that the substrate is split into two layers from the middle and the middle part is removed by processing, so as to form two base substrates 100, each having a crystal layer 100 with crystal grains arranged along a certain direction. Thereby, it is possible that the generation schedule is accelerated, and the cost is saved.

The crystal layer 100a lying in one surface layer of the base substrate 100 means that, with respect to any of top and bottom surfaces of the base substrate 100, the crystal layer 100a lies within a certain range of thickness from one surface of the base substrate 100 to the other surface of it. The thickness of the formed surface layer needs to be determined based on the crystal precipitation temperature, time and so on during thermal treatment of the crystal layer 100a, and no limit will be set on it here.

Furthermore, as crystal grains are distributed evenly in the surface layer, from the microscopic point of view, in the surface layer, the crystal grains are also arranged in a certain direction layer by layer.

Optionally, as illustrated in FIG. 3, thickness of the crystal layer 100a is equal to total thickness of the base substrate 100.

The crystal layer 100a here lies within the entire range of thickness from one surface of the base substrate 100 to the other surface of it. Likewise, sufficient crystal precipitation is implemented by controlling the crystal precipitation temperature, time and so on during thermal treatment, thereby allowing the crystal layer 100a to fill the whole base substrate 100.

Furthermore, as crystal grains are distributed evenly in the base substrate, from the microscopic point of view, in the whole base substrate 100, the crystal grains are also arranged in a certain direction layer by layer.

Here, as the crystal layer 100a with crystal grains arranged along a certain direction is formed by conducting a thermal treatment on an original glass, and as there are defects and a low surface energy on a surface of the original glass substrate, at the preliminary stage of conducting the thermal treatment on the original glass, crystal grains are more easy to precipitate from the surface of the glass substrate firstly. As the heating process goes on, crystal precipitation is carried on more fully, so as to fill the whole glass substrate. Such details that in what temperature range and how long crystal grains can precipitate at the surface of the glass substrate, and to what temperature range and how long it being heated continually makes crystal precipitation be more sufficient to fill the whole glass substrate, are relevant to the substance usable for preparing the crystal layer included in the original glass and so on. For those skilled in the art, the above-mentioned base substrate can be obtained by preparation based on existing substances and technologies.

As the crystal grains are relatively easy to precipitate from a surface of the glass substrate, its thermal treatment process is relatively shorter, and energy consumption of the process and cost also can be saved.

It is to be noted that, the original glass here refers to such glass that substances usable for preparing the crystal layer are contained in a common glass.

In view of excellent photoelectric and piezoelectric coefficients of strontium barium niobate crystals, further preferably, the crystal layer may be a crystal layer of strontium barium niobate.

The crystal layer of strontium barium niobate may be made of an original glass after it is subjected to a thermal treatment. The original glass here may be, such as, the glass where a mixture of SrCO₃, BaCO₃, Nb₂O₅ and SiO₂ usable for preparing the strontium barium niobate crystals is contained in a common glass.

For the original glass herein, its preparation method may include the following process steps, for example.

1). in accordance with a selected composition of raw materials, SrCO₃, BaCO₃, Nb₂O₅ and SiO₂ at a certain ratio are added into a ball milling tank for mixture;

2). alcohol is added into the ball milling tank at the mass ratio of 1:1.2;

3). the ball milling tank is fixed on a ball milling tank machine, the rotational speed of which is regulated to be 400 r/min, the raw materials are ball-milled for 6 h and then are discharged, and the ground raw materials are placed at 100° C. for drying;

4). they are put into a platinum crucible after the drying, placed in a muffle furnace in air atmosphere, heated to 1550° C. from room temperature, and kept at this temperature for 4 h for melting treatment;

5). the molten glass is introduced into a pre-heated mold for casting, and placed in a furnace at 650° C. for 12 h annealing treatment after it is cooled in air for 25 s, so that an internal stress introduced during the molding is eliminated, and an original glass is obtained.

With respect to the crystal layer of strontium barium niobate, it can be obtained by conducting a thermal treatment on the original glass fabricated by the above steps. Where, the thermal treatment process may include the following two stages, for example.

A first stage is a nucleation processing stage, namely, the original glass fabricated as above is heated at a fixed speed of temperature rising, after the temperature is raised from the room temperature to a nucleation temperature, the temperature is kept for a period of time for forming a large number of crystal nuclei.

A second stage is a crystal grain growing stage, namely, on the basis of the above structure, the original glass is continued to be subjected to a thermal treatment at a fixed speed of temperature rising till the temperature reaches a temperature range of crystal precipitation, and subjected to a grain-oriented microcrystallization treatment, so that a crystal layer of strontium barium niobate with crystal grains arranged directionally is obtained.

The crystal layer 100a can be made to only form in a surface layer of the base substrate 100 or fill the whole base substrate 100 by controlling the crystal precipitation temperature, time and so on. Details are set according to actual circumstances, and no limit will be set here.

Furthermore, the grain-oriented microcrystallization treatment is such as: crystal grains are guided to grow in a predetermined direction by means of directional crystal precipitation under a gradient temperature field, and those skilled in the art can make the precipitated crystal grains be arranged along a preset direction based on substances for preparing the crystal layer included in the original glass, the temperature range of crystal precipitation, etc. For example, the gradient temperature field here may be such as a process in which temperature rises up in a gradient manner; the process of gradient temperature rise differs, and the arrangement direction of crystal grains also differs. Therefore, a desired arrangement direction of crystal grains can be formed by the temperature rise process. Only a manner of gradient temperature field is given here as an example of orientation, however, the mode of orientation is not limited according to embodiments of the invention, and other mode of orientation may also be used.

Optionally, as illustrated in FIG. 4, when the display substrate 10 is an array substrate 20, a thin film transistor 300 and a pixel electrode 307 are provided on a surface of the base substrate 100. Certainly, as illustrated in FIG. 4, the base substrate 100 also has a protective layer 306 provided thereon, and the pixel electrode 307 is connected to a drain electrode 305 of the thin film transistor 300 through a via hole provided in the protective layer 306.

The thin film transistor 300 includes a gate electrode 301, a gate insulating layer 302, an active layer 303, a source electrode 304 and the drain electrode 305, which is connected to the pixel electrode 307 through a via hole provided in the protective layer 306.

Here, one thin film transistor 300 and the pixel electrode 307 connected to the drain electrode 305 of the thin film transistor as well as the protective layer between them constitute one display element structure 200.

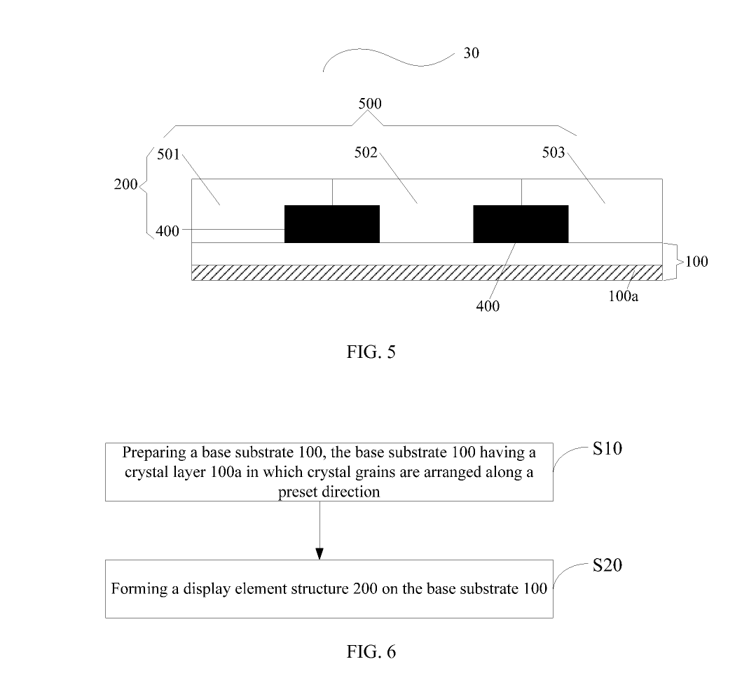

Optionally, as illustrated in FIG. 5, when the display substrate 10 is a color filter substrate 30, a black matrix 400 and a color filter 500 are provided on a surface of the base substrate 100. The color filter includes a red filter 501, a green filter 502 and a blue filter 503. Further, a common electrode 308 (not illustrated in FIG. 5) and so on may also be provided on the surface of the base substrate 100.

Here, for the illustrative convenience, with a color filter substrate 30 that is cell-assembled with an array substrate 20 as an example, a black matrix 400 corresponding to the thin film transistor 300 and a color filter such as the red filter 501 in contact with one side of it constitute one display element structure; likewise, a black matrix 400 corresponding to the thin film transistor 300 and a color filter such as the green filter 502 in contact with one side of it also constitute one display element structure; and a black matrix 400 corresponding to the thin film transistor 300 and a color filter such as the blue filter 503 in contact with one side of it constitute one display element structure as well.

It is to be noted that, FIG. 4 and FIG. 5 merely illustrate the case that a crystal layer 100a of a base substrate in each of the array substrate 20 and the color filter substrate 30 lies in a surface layer, but embodiments of the invention are not limited thereto. The crystal layer 100a may also fill the whole base substrate 100, and details are omitted here.

Because the array substrate 20 and the color filter substrate 30 each include a crystal layer 100a with crystal grains arranged along a preset direction, by means of rationally setting the grain arrangement direction of crystal layers 100a of base substrates 100 located in the array substrate 20 and the color filter substrate 30, respectively, it can replace the role of a polarizer at present when the array substrate 20 and the color filter substrate 30 are cell-assembled to form a liquid crystal display device. A crystal layer 100a of a base substrate 100 located in the array substrate allows an incident light to turn into a polarized light, and the intensity of light of the liquid crystal display device can be controlled by the action of a liquid crystal layer and a crystal layer 100a of a base substrate 100 located in the color filter substrate 30.

It is to be noted that, crystal layers of base substrates for the array substrate 20 and the color filter substrate 30 each are identified by 100a, but in fact, the grain arrangement directions for them may be the same, and may also be different.

According to an embodiment of the invention, there is further provided a manufacturing method of a display substrate. As illustrated in FIG. 6, the method includes the following steps.

S10, a base substrate 100 is prepared, where, the base substrate 100 has a crystal layer 100a in which crystal grains are arranged along a predetermined direction.

Optionally, referring to that illustrated in FIG. 2, the preparing of the base substrate 100 includes: forming the crystal layer 100a at one surface of the base substrate 100.

Optionally, referring to that illustrated in FIG. 3, the preparing of the base substrate 100 include: forming the crystal layer 100a in such a manner that it fills the whole base substrate 100.

Further, the preparing of the base substrate 100 may concretely be: heating an original glass, so that crystal nuclei are formed in the original glass; heating the original glass with the formed crystal nuclei, so that crystal grains grow; conducting a grain-oriented microcrystallization treatment when it reaches a temperature range of crystal precipitation, so as to form a crystal layer 100a with crystal grains arranged in a predetermined direction in the base substrate.

Regarding the manufacturing method of the original glass, reference to the manufacturing method of an original glass for preparing the strontium barium niobate crystal grains in method embodiments can be made, and details are omitted here.

The crystal layer 100a can be made to only form at a surface of the base substrate 100 or fill the whole base substrate 100 by controlling the crystal precipitation temperature, time and so on. Details are set according to actual circumstances, and no limit will be set here.

Further, the grain-oriented microcrystallization treatment is such as: crystal grains are guided to grow in a predetermined direction by means of directional crystal precipitation under a gradient temperature field, and those skilled in the art can make the precipitated crystal grains be arranged along a preset direction based on substances for preparing the crystal layer included in the original glass, the temperature range of crystal precipitation, etc.

S20, the display element structure 200 is formed on the base substrate 100.

Herein, referring to that illustrated in FIG. 4, in the event that the display substrate 10 is an array substrate 20, forming the display element structure 200 on the base substrate 100, for example, may include: forming a gate electrode 301, a gate insulating layer 302, an active layer 303, a source electrode 304 and a drain electrode 305, and a protective layer 306 and a pixel electrode 307 in sequence on the base substrate 100. The drain electrode 305 is connected to the pixel electrode 307 through a via hole provided in the protective layer 306. The gate electrode 301, the gate insulating layer 302, the active layer 303, the source electrode 304 and the drain electrode 305 form the structure of a thin film transistor 300; and one thin film transistor 300 and a pixel electrode connected to the drain electrode 305 of the thin film transistor as well as a protective layer 306 between them form one display element structure 200. In addition, it may further include forming a common electrode 308 (not illustrated in FIG. 4) in correspondence with the pixel electrode and a passivation layer 309 (not illustrated in FIG. 4) between them.

Referring to FIG. 5, in the event that the display substrate 10 is a color filter substrate 30, forming the display element structure 200 on the base substrate 100, for example, may include: forming black matrices 400 disposed at an interval and a color filter 500 on the base substrate 100, where, the color filter includes a red filter 501, a green filter 502 and a blue filter 503 located between the black matrices 400. Further, a common electrode 308 (not illustrated in FIG. 5) may further be formed over the color filter 500.

For the illustrative convenience, with a color filter substrate 30 that is cell-assembled with an array substrate 20 as an example, a black matrix 400 corresponding to the thin film transistor 300 and a color filter such as the red filter 501 in contact with one side of it constitute one display element structure; likewise, a black matrix 400 corresponding to the thin film transistor 300 and a color filter such as the green filter 502 in contact with one side of it also constitute one display element structure; and a black matrix 400 corresponding to the thin film transistor 300 and a color filter such as the blue filter 503 in contact with one side of it constitute one display element structure as well. Of course, in the event that the color filter substrate 30 includes a common electrode 308, the display element structure 200 further includes a common electrode 308 in correspondence with the black matrix 400 and a respective filter (such as the red filter 501).

With respect to a manufacturing method of a display substrate provided by an embodiment of the invention, it includes: preparing a base substrate 100, wherein the base substrate 100 has a crystal layer 100a with crystal grains arranged along a predetermined direction; and forming the display element structure 200 on the base substrate 100. As such, on one hand, the base substrate 100 has a higher mechanical strength than common glass owing to the fact that it has the crystal layer 100a in which crystal grains are arranged orderly, and thus, as compared to a common glass substrate in prior art, the base substrate in the display substrate provided by the invention can avoid from a fragile phenomenon. On the other hand, when the display substrate is applied to a display device, it is applicable to a display equipment that requires an incident light to be a polarized light owing to the fact that the base substrate 100 has the crystal layer 100a with orderly arranged crystal grains that allows an incident light to turn into a polarized light, and thus, as compared to the case in prior art that a polarizer needs to be provided additionally, according to the invention, thickness of the display device can be reduced, and problems caused by the easy wear of a polarizer and poor attachment and the occurrence of mura phenomena can be avoided.

According to an embodiment of the invention, there is further provided a display device, comprising each possible display substrate 10 as stated above.

The display device may be any display device in need of polarization for implementing display, and concretely, it may be a liquid crystal display device, and may be any product or component having a display function, such as a liquid crystal display, a liquid crystal television, a digital photo frame, a cell phone, a tablet computer or the like.

Optionally, the display substrate 10 may be the array substrate 20 or the color filter substrate 30, or the display substrates are the array substrate 20 and the color filter substrate 30, respectively; and the display device further includes a liquid crystal layer 40 disposed between the array substrate 20 and the color filter substrate 30.

When the display substrate 10 is the array substrate 20 alone, the display device further includes a polarizer disposed on a side of the color filter substrate 30 facing away from the liquid crystal layer 40; or, when the display substrate 10 is the color filter substrate 30 alone, the display device further includes a polarizer disposed on a side of the array substrate 20 facing away from the liquid crystal layer 40; or, when the display substrates 10 are the array substrate 20 and the color filter substrate 30, respectively, no polarizer is required.

In the event that the display substrates 10 are the array substrate 20 and the color filter substrate 30, respectively, further preferably, polarizing directions of crystal layers 100a for the base substrate 100 located in the array substrate 20 and the base substrate 100 located in the color filter substrate 30 are perpendicular or in parallel to each other.

Herein, polarizing directions of crystal layers 100a for the base substrate 100 located in the array substrate 20 and the base substrate 100 located in the color filter substrate 30 being perpendicular or in parallel to each other is set based on the principle of the liquid crystal display device. That is, for example, the crystal layer 100a of the base substrate in the array substrate 20 turns lights of a backlight source into polarized lights in a first direction; in the event that polarizing direction of the crystal layer 100a of the base substrate in the color filter substrate 30 is perpendicular to polarizing direction of the crystal layer 100a of the base substrate in the array substrate 20, if after the light is rotated by 90 degrees upon passing through liquid crystals, direction of the polarized light after rotation in liquid crystals is parallel to polarizing direction of the crystal layer 100a of the base substrate of the color filter substrate 30, then the lights exit from the color filter substrate 30 totally, which is a normally white mode; if after the light rotated by 0 degree upon passing through liquid crystals, its direction is parallel to polarizing direction of the crystal layer 100a of the second base substrate 102, then none of it can exit from the color filter substrate, which is a normally black mode.

For the case where polarizing direction of the crystal layer 100a of the base substrate of the color filter substrate 30 is parallel to polarizing direction of the crystal layer 100a of the base substrate of the array substrate 20, the normally white mode as stated above is a normally black mode here, and the normally black mode as stated above is a normally white mode here. Specific processes are similar to descriptions made above, and details are omitted here.

In embodiments of the invention, it may be preferable that polarizing directions of crystal layers 100a for the base substrate 100 located in the array substrate 20 and the base substrate 100 located in the color filter substrate 30 are perpendicular to each other.

Light of the backlight source is turned into polarized lights after it passes through the crystal layer 100a of the base substrate in the array substrate 20, and further, by the action of the liquid crystal layer 40 and the crystal layer 100a of the base substrate of the color filter substrate 30, intensity of outgoing red, green and blue lights can be controlled. Thus, a full-color display is realized.

It is to be noted here that, the same reference numerals are used for the base substrate 100 in the array substrate 20 and the crystal layer 100a located on the base substrate, and for the base substrate in the color filter substrate 30 and the crystal layer 100a located on the base substrate, but during the actual use, locations of crystal layers 100a of base substrates in an array substrate and a color filter substrate may be the same, and may be different, and polarizing directions of the crystal layers 100a of them may be the same, and may be different.

Preferably, the crystal layer 100a in the base substrate 100 in the array substrate 20 is located on a side of the array substrate 20 facing away from the liquid crystal layer 40.

The crystal layer 100a in the base substrate 100 in the color filter substrate 30 is located on a side of the color filter substrate 30 facing away from the liquid crystal layer 40.

As such, the crystal layer 100a is formed in a surface layer of the base substrate 100, and during its manufacturing process, cost and energy consumption of the process can be saved.

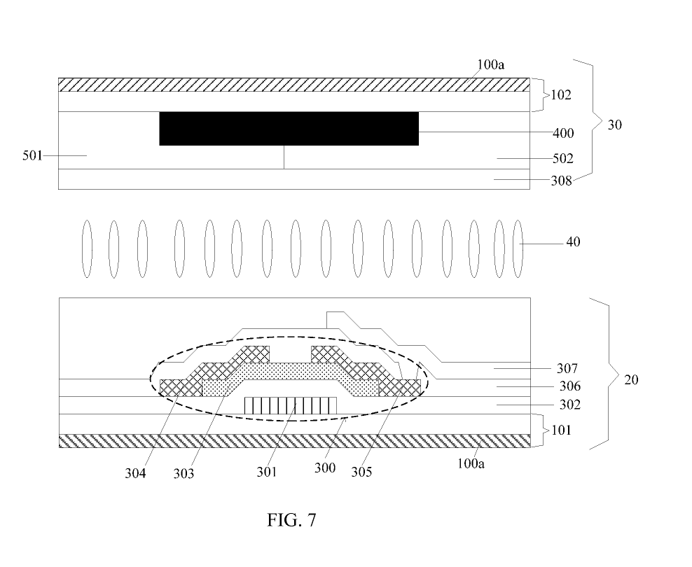

A specific embodiment will be provided below, so as to describe one of display devices as stated above in detail. As illustrated in FIG. 7, the display device includes: an array substrate 10, a color filter substrate 20 and a liquid crystal layer 30 located between the two substrates.

The array substrate 10 includes a first base substrate 101, and a thin film transistor 300 and a pixel electrode 307 provided on the first base substrate 101, and from bottom to top, the thin film transistor 300 sequentially includes a gate electrode 301, a gate insulating layer 302, an active layer 303, a source electrode 304 and a drain electrode 305, which is connected to the pixel electrode 307 through a via hole in a protective layer 306 disposed between the thin film transistor and the pixel electrode. Besides, the array substrate further includes a gate line (not illustrated in the figure) connected to the gate electrode 301 and a data line (not illustrated in the figure) connected to the source electrode 304.

A crystal layer 100a of the first base substrate 101 is provided in a surface layer of the first base substrate facing away from the liquid crystal layer 40; and arranging direction of crystal grains of the crystal layer 100a enables light to be polarized along a first direction. No limit will be set on the concrete thickness of the crystal layer 100a lying in the surface layer of the first base substrate 101 here, which is set according to an actual manufacturing process.

The color filter substrate 20 includes a second base substrate 102, a black matrix 400 and a color filter 500 (not illustrated in FIG. 7) provided on the second base substrate 102, and the color filter 500 may include a red filter 501, a green filter 502 and a blue filter 503 (not illustrated in FIG. 7). Besides, it may further include a common electrode 308.

A crystal layer 100a of the second base substrate 102 is provided in a surface layer of the second base substrate facing away from the liquid crystal layer 40; and arranging direction of crystal grains of the crystal layer 100a enables light to be polarized along a second direction that is perpendicular to the first direction. No limit will be set on the concrete thickness of the crystal layer 100a lying in the surface layer of the second base substrate 102 here, which is set according to an actual manufacturing process.

With respect to the display device having the above structure, the crystal layer 100a of the first base substrate 101 in the array substrate 20 turns light of a backlight source into polarized light in a first direction; if after they are rotated by 90 degrees upon passing through liquid crystals, direction of it is parallel to polarizing direction of the crystal layer 100a of the second base substrate 102 of the color filter substrate 30, then the light exits from the color filter substrate 30 totally, which is a normally white mode; if after it are rotated by 0 degree upon passing through liquid crystals, direction of them is parallel to polarizing direction of the crystal layer 100a of the second base substrate 102, then none of it can exit from the color filter substrate, which is a normally black mode.

Light of the backlight source is turned into polarized lights after it passes through the crystal layer 100a of the first base substrate 101 in the array substrate 20, and further, by the action of the liquid crystal layer 40 and the crystal layer 100a of the second base substrate 102 of the color filter substrate 30, intensity of outgoing red, green and blue light can be controlled. Thus, a full-color display is realized.

The display panel provided by embodiments of the invention may be applicable to liquid crystal display devices in an Advanced Super Dimension Switch mode, in an In-Plane Switching mode and in other modes. The description of a core technical characteristic of the advanced super dimension switch technique is that, a multi-dimensional electric field is formed by an electric field produced at edges of slit electrodes on the same plane and an electric field produced between a layer of the slit electrodes and a layer of a plate-like electrode, so as to allow liquid crystal molecules with every orientations within a liquid crystal cell, which are located directly above the electrode and between the slit electrodes, to be rotated, and thereby the work efficiency of liquid crystals is enhanced and the transmissive efficiency is increased. With the advanced super dimension switch technique, the picture quality of Thin Film Transistor-Liquid Crystal Display (briefly called as TFT-LCD) products can be improved, and it has the advantages of high resolution, high transmittance, low power consumption, wide viewing angle, high aperture ratio, low chromatic aberration, push Mura-free, and so on.

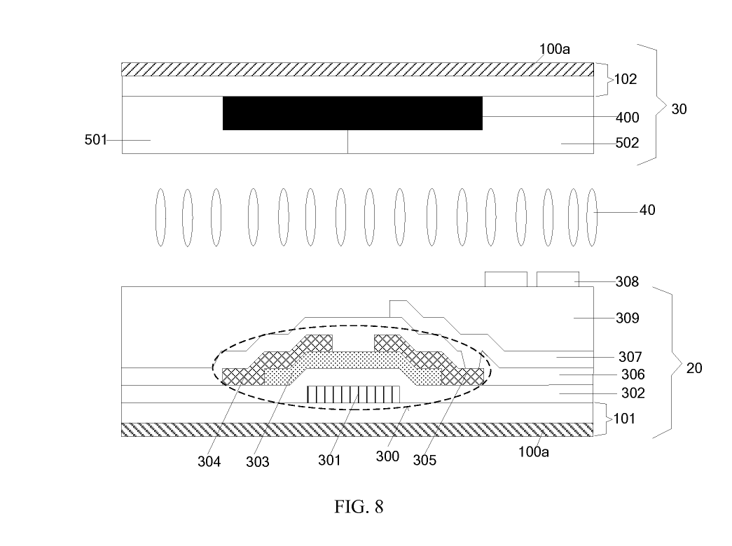

Thus, for a liquid crystal display device of an advanced super dimension switch technique mode, as illustrated in FIG. 8, the array substrate 20 further includes a passivation layer 309 and a common electrode 308.

In this case, one thin film transistor 300, a pixel electrode 307 connected to a drain electrode 305 of the thin film transistor and a protective layer 306 between them, and a common electrode 308 corresponding to the pixel electrode 307 and a passivation layer 309 between them constitute one display element structure 200.

Descriptions made above are merely exemplary embodiments of the invention, but are not used to limit the protection scope of the invention. The protection scope of the invention is determined by attached claims.

1. A display substrate, comprising a base substrate and a display element structure located on the base substrate, wherein, the base substrate has a crystal layer in which crystal grains are arranged in a predetermined direction.

2. The display substrate according to claim 1, wherein, the crystal layer lies in one surface layer of the base substrate.

3. The display substrate according to claim 1, wherein, a thickness of the crystal layer is equal to a total thickness of the base substrate.

4. The display substrate according to claim 1, wherein, the crystal layer is a strontium barium niobate crystal layer.

5. The display substrate according to claim 1, wherein, the base substrate is a microcrystalline glass substrate.

6. The display substrate according to claim 1, wherein, the display substrate is an array substrate, and the display element structure on the base substrate includes a thin film transistor and a pixel electrode.

7. The display substrate according to claim 1, wherein, the display panel is a color filter substrate, and the display element structure on the base substrate includes a black matrix and a color filter.

8. The display substrate according to claim 2, wherein, the crystal layer lies in a surface layer of the base substrate at a side opposite to that for forming the display element structure.

9. A manufacturing method of a display substrate, comprising the following steps:
preparing a base substrate, wherein, the base substrate has a crystal layer in which crystal grains are arranged in a predetermined direction;
forming a display element structure on the base substrate.

10. The manufacturing method of the display substrate according to claim 9, wherein, the crystal layer is formed at one surface of the base substrate.

11. The manufacturing method of the display substrate according to claim 9, wherein, a thickness of the crystal layer is equal to a total thickness of the base substrate.

12. The manufacturing method of the display substrate according to claim 9, wherein, the preparing of the base substrate includes:
heating an original glass, so that crystal nuclei are formed in the original glass;
heating the original glass with the formed crystal nuclei, so that crystal grains grow;
conducting a grain-oriented microcrystallization treatment when it reaches a temperature range of crystal precipitation, so as to form a crystal layer with crystal grains arranged in the predetermined direction in the base substrate.

13. The manufacturing method of the display substrate according to claim 12, wherein, in the grain-oriented microcrystallization treatment, a gradient temperature field is applied to the glass, so that crystal grains are guided to grow according to the predetermined direction.

14. A display device, comprising the display substrate according to claim 1.

15. The display device according to claim 14, wherein, the display device includes two of the display substrates that are disposed opposite to each other, one of the display substrates is an array substrate, and the other one is a color filter substrate;
the display device further includes a liquid crystal layer disposed between the array substrate and the color filter substrate.

16. The display device according to claim 15, wherein, the crystal layer of the base substrate located in the array substrate and the crystal layer of the base substrate located in the color filter substrate have a polarizing function, and polarizing directions of the crystal layers of the base substrate located in the array substrate and the base substrate located in the color filter substrate are perpendicular to each other.

17. The display device according to claim 15, wherein, the crystal layer in the base substrate in the array substrate is located on a side of the array substrate facing away from the liquid crystal layer;
the crystal layer in the base substrate in the color filter substrate is located on a side of the color filter substrate facing away from the liquid crystal layer.

18. The display substrate according to claim 2, wherein, the crystal layer is a strontium barium niobate crystal layer.

19. The display substrate according to claim 2, wherein, the base substrate is a microcrystalline glass substrate.

20. The display substrate according to claim 2, wherein, the display substrate is an array substrate, and the display element structure on the base substrate includes a thin film transistor and a pixel electrode.
